(19) United States
(12) Patent Application Publication
(10) Pub. No.: US 2023/0075825 A1
(43) Pub. Date: Mar. 9, 2023

(54) Charged Particle Beam Drawing Apparatus and Control Method for Charged Particle Beam Drawing Apparatus

(71) Applicant: JEOL Ltd., Tokyo (JP)

(72) Inventor: Yukinori Aida, Tokyo (JP)

(21) Appl. No.: 17/939,425

(22) Filed: Sep. 7, 2022

(30) Foreign Application Priority Data
Sep. 8, 2021 (JP) 2021-146211

(51) Int. Cl. H01J 37/317; H01J 37/304

(52) U.S. Cl. CPC H01J 37/3174; H01J 37/3045; H01J 2237/24578

(57) ABSTRACT

Provided is a charged particle beam drawing apparatus including a measurement unit that scans a reference mark disposed on a stage with a charged particle beam to detect a position of the reference mark, and measures a positional deviation amount of the charged particle beam, based on the detected position; and a positional correction unit that corrects a drawing position based on the measured positional deviation amount. A plurality of the reference marks is disposed on the stage, and the measurement unit switches from one of the reference marks used for the measurement of the positional deviation amount to another one of the reference marks that is not used yet, when a predetermined condition has been satisfied.

### CROSS REFERENCE TO RELATED APPLICATION

This application claims priority to Japanese Patent Application No. 2021-146211 filed Sep. 8, 2021, the disclosure of which is hereby incorporated by reference in its entirety.

### BACKGROUND OF THE INVENTION

### Field of the Invention

The present invention relates to a charged particle beam drawing apparatus and a control method for the charged particle beam drawing apparatus.

### Description of Related Art

In a conventional electronic beam drawing apparatus, a method of setting a mark on a stage, scanning the mark with an electron beam, detecting a beam drift amount of detecting a mark position, and performing drift correction, is known (e.g. Japanese Patent Application Publication No. H10-199786).

If scanning the mark with an electron beam is repeated to detect the mark position, the mark may be damaged and deteriorate by the irradiation with the electron beam. Thereby the accuracy to detect the beam drift amount may drop, and the drawing position accuracy may drop as well.

### SUMMARY OF THE INVENTION

The invention can provide a charged particle beam drawing apparatus and a control method for the charged particle beam drawing apparatus, which can suppress a drop in drawing position accuracy.

According to the first aspect of the invention, there is provided a charged particle beam drawing apparatus that irradiates a material placed on a stage with a charged particle beam to draw a pattern on the material, the charged particle beam drawing apparatus including:

a measurement unit that scans a reference mark disposed on the stage with the charged particle beam to detect a position of the reference mark, and measures a positional deviation amount of the charged particle beam, based on the detected position; and

a positional correction unit that corrects a drawing position based on the measured positional deviation amount,

a plurality of the reference marks being disposed on the stage, and

the measurement unit switching from one of the reference marks used for the measurement of the positional deviation amount to another one of the reference marks that is not used yet, when a predetermined condition has been satisfied.

According to the second aspect of the invention, there is provided a control method for a charged particle beam drawing apparatus that irradiates a material placed on a stage with a charged particle beam to draw a pattern on the material, the control method including:

a measurement step of scanning a reference mark disposed on the stage with the charged particle beam to detect a position of the reference mark, and measuring a positional deviation amount of the charged particle beam, based on the detected position; and

a positional correction step of correcting a drawing position based on the measured positional deviation amount,

a plurality of the reference marks being disposed on the stage, and

the measurement step switching from one of the reference marks used for the measurement of the positional deviation amount to another one of the reference marks that is not used yet, when a predetermined condition has been satisfied.

### BRIEF DESCRIPTION OF THE DRAWINGS

FIG. 1 is a diagram illustrating an example of a configuration of an electron beam drawing apparatus (charged particle beam drawing apparatus) according to an embodiment of the invention).

FIG. 2 is a plan view of a stage.

FIG. 3 is a diagram illustrating an example of a plurality of reference marks.

FIG. 4 is a flow chart illustrating a processing flow of a processing unit.

### DESCRIPTION OF THE INVENTION

(1) According to an embodiment of the invention, there is provided a charged particle beam drawing apparatus that irradiates a material placed on a stage with a charged particle beam to draw a pattern on the material, the charged particle beam drawing apparatus including:

a measurement unit that scans a reference mark disposed on the stage with the charged particle beam to detect a position of the reference mark, and measures a positional deviation amount of the charged particle beam, based on the detected position; and

a positional correction unit that corrects a drawing position based on the measured positional deviation amount,

a plurality of the reference marks being disposed on the stage, and

the measurement unit switching from one of the reference marks used for the measurement of the positional deviation amount to another one of the reference marks that is not used yet, when a predetermined condition has been satisfied.

According to an embodiment of the invention, there is provided a control method for a charged particle beam drawing apparatus that irradiates a material placed on a stage with a charged particle beam to draw a pattern on the material, the control method including:

a measurement step of scanning a reference mark disposed on the stage with the charged particle beam to detect a position of the reference mark, and measuring a positional deviation amount of the charged particle beam, based on the detected position; and

a positional correction step of correcting a drawing position based on the measured positional deviation amount,

a plurality of the reference marks being disposed on the stage, and

the measurement step switching from one of the reference marks used for the measurement of the positional deviation amount to another one of the reference marks that is not used yet, when a predetermined condition has been satisfied.

According to the above embodiments, by switching from one of the reference marks used for the measurement of the positional deviation amount to another one of the reference marks that is not used yet, when a predetermined condition has been satisfied, a drop in drawing position accuracy caused by deterioration of the reference mark can be suppressed.

(2) In the charged particle beam drawing apparatus, the measurement unit may determine whether the predetermined condition is satisfied or not, based on the number of times of scanning the reference marks with the charged particle beam.

In the above control method for the charged particle beam drawing apparatus, whether the predetermined condition is satisfied or not may be determined, based on the number of times of scanning the reference marks with the charged particle beam in the measurement step.

(3) In the above charged particle beam drawing apparatus, the measurement unit may determine whether the predetermined condition is satisfied or not, based on the elapsed time since use of the reference marks started.

In the above control method for the charged particle beam drawing apparatus, whether the predetermined condition is satisfied or not may be determined, based on the elapsed time since use of the reference marks started in the measurement step.

(4) In the charged particle beam drawing apparatus, the measurement unit may determine whether the predetermined condition is satisfied or not, based on a signal that is generated from the reference marks when the reference marks are scanned with the charged particle beam.

In the above control method for the charged particle beam drawing apparatus, whether the predetermined condition is satisfied or not may be determined, based on a signal that is generated from the reference marks when the reference marks are scanned with the charged particle beam in the measurement step.

Preferred embodiments of the invention will be described in detail below with reference to the drawings. It is noted that the following embodiments do not unduly limit the scope of the invention as stated in the claims. Furthermore, all of the components described below are not necessarily essential requirements of the invention.

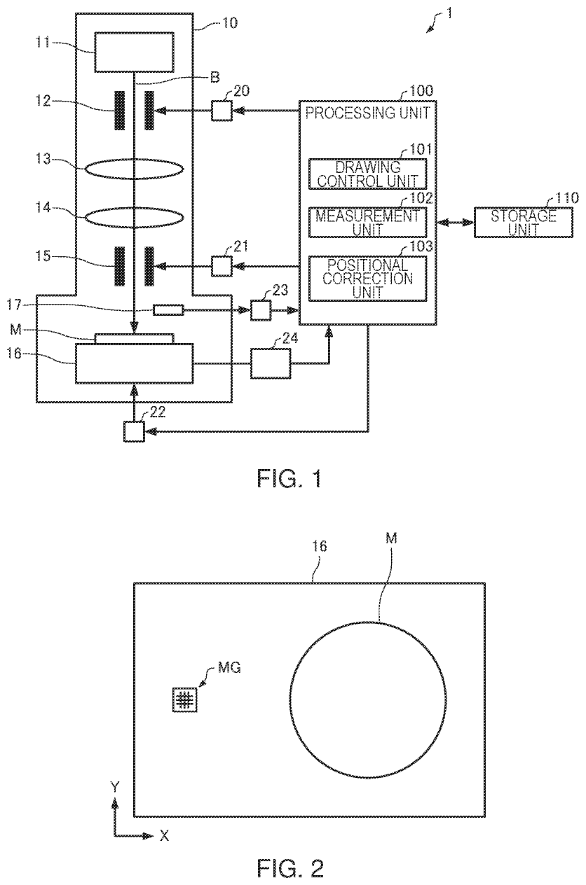

FIG. 1 is a diagram illustrating a configuration of an electron beam drawing apparatus (an example of a charged particle beam drawing apparatus) according to an embodiment of the invention. The electron beam drawing apparatus of the present embodiment may be a configuration in which a part of the composing elements (each portion) of FIG. 1 is omitted.

The electron beam drawing apparatus 1 includes an electron beam drawing apparatus main unit 10, a processing unit 100 and a storage unit 110. The electron beam drawing apparatus main unit 10 includes an electron gun 11 that generates an electron beam B, a blanker 12 that performs blanking of the electron beam B, an irradiation lens system 13, an objective lens 14, a deflector 15, a stage 16 on which a drawing material M is placed, an electron detector 17, a blanker control circuit 20 that controls the blanker 12, a deflector driving circuit 21 that drives the deflector 15, a stage driving circuit 22 that drives the stage 16, an amplifier 23, and a laser length-measuring device 24 that measures the position of the stage 16 (a laser length-measuring device that measures the position in the X axis direction and a laser length-measuring device that measures the position in the Y axis direction). The electron beam B generated from the electron gun 11 is emitted onto the drawing material M placed on the stage 16 via the irradiation lens system 13 and the objective lens 14. The irradiation position on the drawing material M can be changed by moving the stage 16 and controlling the deflector 15.

The storage unit 110 stores programs, various data, pattern data and the like, to make the computer to function as each part of the processing unit 100, and to function as a work area of the processing unit 100, and this function can be implemented by a hard disk, RAM or the like.

The processing unit 100 includes a drawing control unit 101, a measurement unit 102 and a positional correction unit 103. The function of the processing unit 100 can be implemented by such hardware as various processors (e.g. CPU, DSP), and programs.

The drawing control unit 101 controls the blanker control circuit 20, the deflector driving circuit 21 and the stage driving circuit 22 based on the pattern data, programs, and the like stored in the storage unit 110, so as to control the drawing of a pattern on the drawing material M by irradiation with the electron beam B. A region on the drawing material M is divided into a plurality of fields (ranges in which the deflector 15 can deflect the electron beam B), and the drawing control unit 101 controls the stage driving circuit 22 to move the stage 16 to the drawing target field, and controls the deflector driving circuit 21 and the blanker control circuit 20 to draw the pattern by being scanned with the electron beam B within this field.

By controlling the blanker control circuit 20, the deflector driving circuit 21 and the stage driving circuit 22, the measurement unit 102 scans a reference mark (described later) disposed on the stage 16 with the electron beam B, and detects the position of the reference mark based on a detection signal (signal amplified by the amplifier 23) from the electron detector 17 which detects a signal (secondary electrons, backscattered electrons) generated from the reference mark by the scanning. In other words, the measurement unit 102 detects the position of the reference mark based on the position of the stage 16 (position measured by the laser length-measuring device 24) when the reference mark was detected using the detection signal of the electron detector 17. Then the measurement unit 102 detects the position of the reference mark in each predetermined cycle during drawing of the pattern, and measures the difference between the position detected the last time and the position detected this time, as the positional deviation amount of the electron beam B (beam drift amount).

The positional correction unit 103 corrects the drawing position (electron beam position) based on the positional deviation amount measured by the measurement unit 102. The drawing position is corrected by providing values (−Δx, −Δy), which are values of which signs are inverted from the signs of the measured positional deviation amount (Δx, Δy), to the deflector 15 (deflector driving circuit 21).

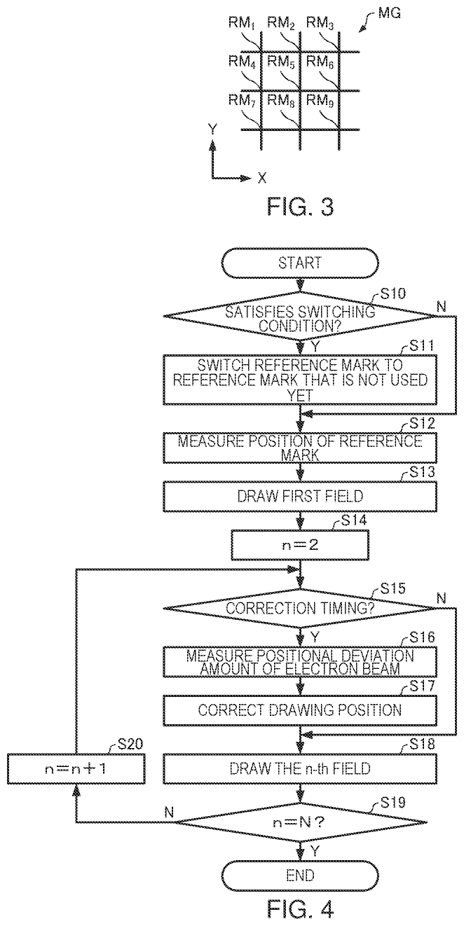

FIG. 2 is a plan view of the stage 16. In the example in FIG. 2, a reference mark group MG, including a plurality of reference marks, is disposed at a predetermined position on the left of the drawing material M (semiconductor wafer) placed on the stage 16. The reference mark group MG is constituted of a meshed metal (gold) formed on a silicon substrate, for example. As illustrated in FIG. 3, a cross-shaped mark, of which center is each intersection of the mesh constituting the reference mark group MG, becomes the reference mark RM (RM₁ to RM₉) respectively. In other words, in the example illustrated in FIG. 2 and FIG. 3, nine reference marks, RM₁ to RM₉ are disposed on the stage 16. Each position (design position) of the plurality of reference marks RM is stored in the storage unit 110. The measurement unit 102 moves the stage 16 based on the design position of a reference mark RM, and scans the region around this reference mark RM with the electron beam B in the X axis direction and Y axis direction, then based on the detection signals received from the electron detector 17 at this time, the measurement unit 102 moves the stage 16 so that this optical axis matches with the center (intersection of the cross shape) of this reference mark RM. Then the measurement unit 102 detects the position of the stage 16 at this time as the position of the reference mark RM (measurement position).

If scanning the reference mark RM with the electron beam B is repeated here to detect the position of the reference mark RM, the reference mark RM may be damaged and deteriorate by the irradiation with the electron beam B, which may drop the detection accuracy of the positional deviation amount and cause a drop in the drawing position accuracy. Therefore, in the present embodiment, the reference mark RM used for measurement of the positional deviation amount is switched to the reference mark RM that is not used yet, when a predetermined switching condition (predetermined condition) has been satisfied. For example, in the case of using the reference marks RM₁ to RM₉ in this sequence, if the switching condition is satisfied for the reference mark RM₁, the reference mark RM is switched to the reference mark RM₂, and if the switching condition is satisfied for the reference mark RM₂, the reference mark RM is switched to the reference mark RM₃, and hereafter the reference mark is switched in the same manner.

Whether the switching condition is satisfied or not for the reference mark RM may be determined based on a number of times this reference mark RM is scanned with the electron beam B. In this case, it is determined that the switching condition is satisfied for this reference mark RM when the number of times of scanning this reference mark RM with the electron beam B reaches a predetermined value. Further, whether the switching condition is satisfied or not for this reference mark RM may be determined based on the elapsed time since the start of using this reference mark RM. In this case, it is determined that the switching condition is satisfied for this reference mark RM when the elapsed time since the start of using this reference mark RM reaches a predetermined value. Furthermore, whether the switching condition is satisfied or not for the reference mark RM may be determined based on the signal that is generated from this reference mark RM in accordance with the scanning with the electron beam B (detection signal from the electron detector 17). For example, it may be determined that the switching condition is satisfied for this reference mark RM in the case where dispersion (standard deviation) of the detection signals from the electron detector 17 when the reference mark RM is scanned with the electron beam B for a predetermined number of times is a predetermined value or more, or it may be determined that the switching condition is satisfied for this reference mark RM in the case where the difference between the detection signal from the electron detector 17 when the reference mark RM is scanned with the electron beam B and a reference value acquired in advance (e.g. detection signal that is acquired at first scanning) is a predetermined value or more (the correction value is a predetermined value or less). Furthermore, whether the switching condition is satisfied or not may be determined by an arbitrary combination of the number of times of scanning with the electron beam B, the elapsed time from the start of use, and the detection signal from the electron detector 17.

By determining whether the switching condition is satisfied or not based on the number of times of scanning with the electron beam B, the elapsed time from the start of use, and the detection signal from the electron detector 17 like this, the reference mark RM can be switched to the reference mark RM that is not used yet, before the reference mark RM deteriorates, and a drop in drawing position accuracy caused by deterioration of the reference mark RM can be suppressed.

Now an example of the processing by the processing unit 100 will be described with reference to a flow chart in FIG. 4. First the measurement unit 102 determines whether the switching condition is satisfied or not for the reference mark RM that is currently in use (step S10). For example, it is determined that the switching condition is satisfied for the reference mark RM that is currently in use in the case where the number of times of scanning reaches a predetermined value, in the case where the elapsed time from the start of use reaches a predetermined value, or in the case where the dispersion of the detection signals from the electron detector 17 after a predetermined number of times of scanning just performed is a predetermined value or more. If it is determined that the switching condition is satisfied (Y in step S10), the measurement unit 102 switches the reference mark RM from the reference mark RMₙ that is currently in use to the reference mark RMₙ₊₁ that is not used yet (step S11). In other words, the reference mark RMₙ₊₁ that is not used yet is set as the reference mark RM that is currently in use. In the case of determining the switching condition based on the elapsed time from the start of use at this time, the date and time when use of the reference mark RM started is stored in the storage unit 110.

Then the measurement unit 102 scans the reference mark RM currently in use with the electron beam B, and measures the position of this reference mark RM (step S12). In the case of determining the switching condition based on the number of times of scanning here, the counter of the number of times of scanning is incremented for this reference mark RM currently in use. Then the drawing control unit 101 performs a control to draw a pattern in a first field (initial field), making the measured position of the reference mark RM as a reference (setting this position as an origin of the stage coordinate system) (step S13). Then the drawing control unit 101 sets 2 for variable n (step S14).

Then the positional correction unit 103 determines whether it is a correction timing to correct the drawing position (step S15). For example, the positional correction unit 103 determines that it is the correction timing in the case where a number of drawn fields reaches a predetermined value since the previous correction of the drawing position, or in the case where the elapsed time is reached since the previous correction of the drawing position. If it is the correction timing (Y in step S15), the measurement unit 102 scans the reference mark RM that is currently in use with the electron beam B, and measures the position of this reference mark RM, and measures the positional deviation amount of the electron beam B based on the difference from the position of the reference mark RM measured the last time (step S16). In the case of determining the switching condition based on the number of times of scanning here, the counter of the number of times of scanning is incremented for this reference mark RM currently in use. Then the positional correction unit 103 corrects the drawing position based on the measured positional deviation amount (step S17).

Then the drawing control unit 101 performs a control to draw a pattern in the n-th field (step S18). Then the drawing control unit 101 determines whether the variable n reaches N (N is a total number of fields) (step S19), and if the variable n does not reach N (N in step S19), 1 is added to the variable n (step S20), and processing returns to step S15. Hereafter the processing steps S15 to S20 are repeated until the variable n reaches N (until drawing completes).

The invention is not limited to the above mentioned embodiments, but may be modified in various ways. The invention includes configurations that are substantially the same (for example, in functions, methods, and results, or in objectives and effects) as the configurations described in the embodiments. The invention also includes configurations obtained by replacing non-essential elements of the configurations described in the embodiments with other elements. The invention also includes configurations having the same effects as those of the configurations described in the embodiments, or configurations capable of achieving the same objectives as those of the configurations described in the embodiments. The invention further includes configurations obtained by adding known art to the configurations described in the embodiments.

Embodiments of the invention have been described in detail above, but a person skilled in the art will readily appreciate that various modifications can be made from the embodiments without materially departing from the novel teachings and effects of the invention. Accordingly, all such modifications are assumed to be included in the scope of the invention.

What is claimed is:

1. A charged particle beam drawing apparatus that irradiates a material placed on a stage with a charged particle beam to draw a pattern on the material, the charged particle beam drawing apparatus comprising:
a measurement unit that scans a reference mark disposed on the stage with the charged particle beam to detect a position of the reference mark, and measures a positional deviation amount of the charged particle beam, based on the detected position; and
a positional correction unit that corrects a drawing position based on the measured positional deviation amount,
wherein a plurality of the reference marks are disposed on the stage, and
wherein the measurement unit switches from one of the reference marks used for the measurement of the positional deviation amount to another one of the reference marks that is not used yet, when a predetermined condition has been satisfied.

2. The charged particle beam drawing apparatus according to claim 1, wherein
the measurement unit determines whether the predetermined condition is satisfied or not, based on the number of times of scanning the reference marks with the charged particle beam.

3. The charged particle beam drawing apparatus according to claim 1, wherein
the measurement unit determines whether the predetermined condition is satisfied or not, based on an elapsed time since use of the reference marks started.

4. The charged particle beam drawing apparatus according to claim 1, wherein
the measurement unit determines whether the predetermined condition is satisfied or not, based on a signal that is generated from the reference marks when the reference marks are scanned with the charged particle beam.

5. A control method for a charged particle beam drawing apparatus that irradiates a material placed on a stage with a charged particle beam to draw a pattern on the material, the control method comprising:
a measurement step of scanning a reference mark disposed on the stage with the charged particle beam to detect a position of the reference mark, and measuring a positional deviation amount of the charged particle beam, based on the detected position; and
a positional correction step of correcting a drawing position based on the measured positional deviation amount,
wherein a plurality of the reference marks are disposed on the stage, and
wherein the measurement step switches from one of the reference marks used for the measurement of the positional deviation amount to another one of the reference marks that is not used yet, when a predetermined condition has been satisfied.
